(19) United States
(12) Patent Application Publication
(10) Pub. No.: US 2017/0265311 A1
(43) Pub. Date: Sep. 14, 2017

(54) METHOD OF FILLING VIAS WITH INK

(71) Applicants: YARIV PINTO, Petah Tiqwa (IL); Eli Asulin, Yokneam Illit (IL); Dotan Avera, Rosh Ha'ayin (IL); Jankiel Kimelblat, Raanana (IL)

(72) Inventors: YARIV PINTO, Petah Tiqwa (IL); Eli Asulin, Yokneam Illit (IL); Dotan Avera, Rosh Ha'ayin (IL); Jankiel Kimelblat, Raanana (IL)

(21) Appl. No.: 15/456,528

(22) Filed: Mar. 12, 2017

Related U.S. Application Data
(60) Provisional application No. 62/307,585, filed on Mar. 14, 2016.

(51) Int. Cl. H05K 3/40; H05K 3/12; H05K 3/00

(52) U.S. Cl. CPC H05K 3/4053; H05K 3/007; H05K 3/1283; H05K 3/125; H05K 2203/0191; H05K 2203/1105; H05K 2203/122

(57) ABSTRACT

A method for selective processing of a panel, the method may include receiving a panel that has a bottom side and a top side and comprises a first group of drilled holes and a second group of drilled holes; at least partially sealing a bottom of any through hole of the first group; filling, by a selective filing process, any drilled hole of the first group that has a top opening to provide at least partially filled drilled holes of the first group without filling the second group of drilled holes; and plugging, by a selective plugging process, a top of any drilled hole of the first group.

### RELATED APPLICATIONS

This application claims priority from U.S. provisional patent Ser. No. 62/307,585 filing date Mar. 14 2016, which is incorporated herein by reference.

### BACKGROUND

A through via is a via that is open at both sides of a panel (such as but not limited to a printed circuit board. A blind vias is a via that is closed on one side of the panel and is open on another side of the panel. A buried via is a via that is not visible from any side of the panel.

Any via may be filled to provide a filled via or may remain open to provide an open via.

A filled via may be filled with an intermediate insulating material and eventually may support a top conductive element.

A panel that includes open vias and filled vias is manufactured by (a) performing a first drilling phase that includes drilling first holes for the filled vias and not for the open vias, (b) performing a first non-selective coating process for coating the sidewalls of the first holes with conductive material, (c) filling the first holes with the intermediate material, (d) performing a second drilling phase that includes drilling second holes for the open vias, and (e) performing a second non-selective coating process for coating the sidewalls of the second holes and for forming the top conductive elements.

The two separate drilling stages, doubles the effort and increases the risk of misregistration of the vias to the pads.

There is a need to provide a solution that allows filling such vias selectively, thus saving significant time and process complications.

### SUMMARY

A method as disclosed in the claims.

There may be provided a method for selective processing of a panel, the method may include receiving a panel that has a bottom side and a top side and may include a first group of drilled holes and a second group of drilled holes; at least partially sealing a bottom of any through hole of the first group; filling, by a selective filing process, any drilled hole of the first group that has a top opening to provide at least partially filled drilled holes of the first group without filling the second group of drilled holes; and plugging, by a selective plugging process, a top of any drilled hole of the first group.

The at least partially sealing may include positioning at least one sealing element below the bottom side of the panel; and positioning the panel on the at least one sealing element so that the at least one sealing element at least partially seals the bottom of any through hole of the first group.

The at least one sealing element may include multiple spaced apart sealing elements.

The at least one sealing element is made of a flexible and porous material.

The at least one sealing element may include an adhesive material.

The at least one sealing element may include a pressure sensitive adhesive film.

The at least partially sealing may include attaching at least one sealing element to the bottom side of the panel so that the at least one sealing element at least partially seals the bottom of any through hole of the first group.

The method may include detaching the at least one sealing element from the bottom side of the panel.

The method may include filling any gap formed in any partially filled hole due to the at least one sealing element.

The selective filing process may differ from the selective plugging process by at least one printing parameter.

The at least one printing parameter may include filling materials used for printing, a size of filling material drops, a filling material viscosity, a printing rate, a curing parameter, and a jetting frequency.

The method may include forming a conduit for conveying a filling material towards a drilled hole of the first group that has a top opening, during the selective filing process.

The method may include forming a funnel for conveying a filling material towards a drilled hole of the first group that has a top opening, during the selective filling process.

The at least partially sealing may include sealing the bottom of any through hole of the first group.

The plugging of the selective plugging process may include curing filling material used for sealing any drilled hole of the first group that has a top opening.

The method may include printing a material on the top side of the panel after plugging, by the selective plugging process, the top of any drilled hole of the first group.

The method may include printing a material on the top side of the panel while plugging, by the selective plugging process, the top of any drilled hole of the first group.

The selective filling process may include filling of any drilled hole of the first group that has the top opening with a disposable material; and removing the disposable material at a point in time that follows the plugging, by the selective plugging process, the top of any drilled hole of the first group.

The method may include removing the disposable material by melting the disposable material.

The method may include removing the disposable material by heating the disposable material.

The disposable material may be wax.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1-3 illustrate examples of methods;

FIG. 4 illustrates examples of a bottom side of a panel and various masks;

FIG. 5 illustrates examples of a top side of a panel and a mask;

FIG. 6 illustrates an example of a top side of a panel, a bottom side of the panel and a cross section of the panel;

FIG. 7 illustrates examples of a panel during various steps of the methods of FIGS. 1-3;

FIG. 8 illustrates an example of a system; and

FIGS. 9-10 illustrate examples of parts of a printed circuit board (PCB) that include sealed vias as well as pads and a solder mask.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

There are provided method for filling vias of a printed circuit board. The terms vias and drilled holes are used in an interchangeable manner.

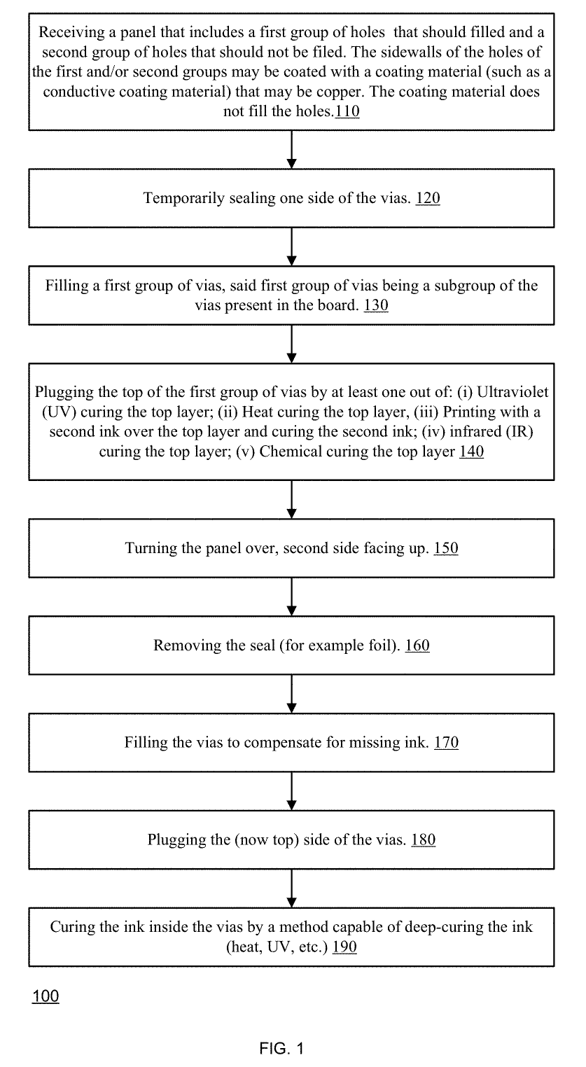

FIG. 1 illustrates method 100 according to an embodiment of the invention.

Method 100 may start by step 110 of receiving a panel that includes a first group of holes that should be filled and a second group of holes that should not be filled. The sidewalls of the holes of the first and/or second groups may be coated with a coating material (such as a conductive coating material) that may be copper. The coating material does not fill the holes.

Step 110 may be followed by step 120 of temporarily sealing one side of the vias (in case of through hole—in case of blind via, this step may be skipped)—could be done with a pressure sensitive adhesive foil or any other detachable element.

Step 120 may be followed by step 130 of filling a first group of vias, said first group of vias being a subgroup of the vias present in the board. The temporary seal prevents the leakage of the ink through the vias.

Step 130 may be followed by step 140 of plugging the top of the first group of vias by at least one out of: [symbol]
i. UV curing the top layer.
ii. Heat curing the top layer
iii. Printing with a second ink over the top layer and curing the second ink.
iv. IR curing the top layer.
v. Chemical curing the top layer
b. Turning the panel over, second side facing up.
c. Removing the temporary sealing.
d. Filling the vias to compensate for missing ink if needed.
e. Plugging the (now top) side of the vias. by at least one out of:
   i. UV curing the top layer.
   ii. Heat curing the top layer
   iii. Printing with a second ink over the top layer and curing the second ink.
   iv. IR curing the top layer.
   v. Chemical curing the top layer
f. Curing the ink inside the vias by a method capable of deep-curing the ink (heat, UV, etc.)

The selective injection of ink into the vias may be executed by a CNC machine equipped with liquid injectors, or by inkjet.

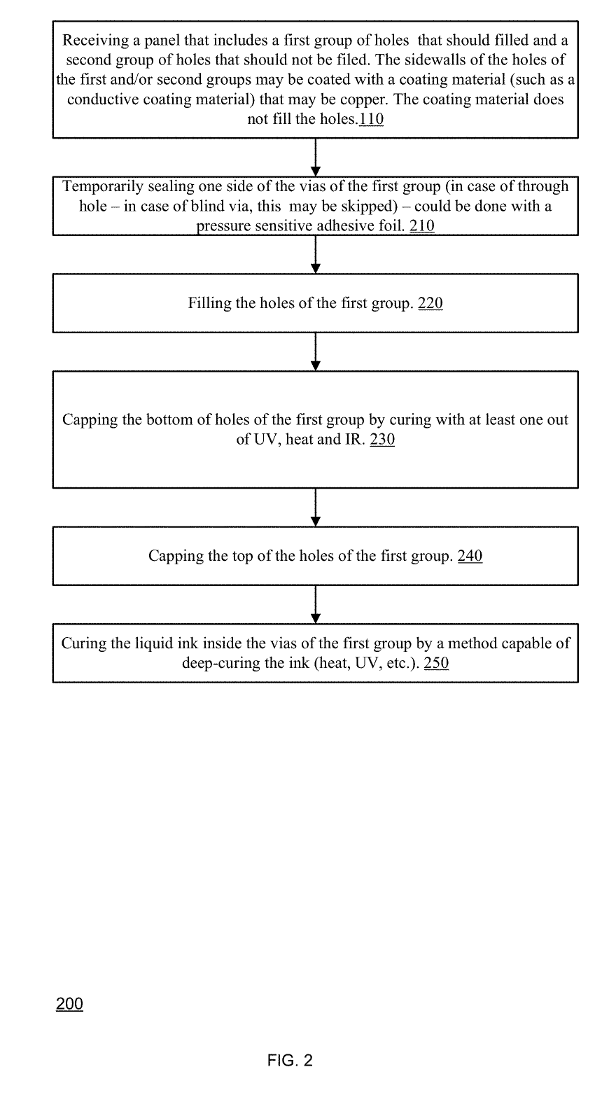

FIG. 2 illustrates method 200 according to an embodiment of the invention.

Method 200 may start by step 110.

Step 110 may be followed by step 210 of temporarily sealing one side of the vias of the first group (in case of through hole—in case of blind via, this step may be skipped)—could be done with a pressure sensitive adhesive foil.

Step 210 may be followed by step 220 of filling the holes of the first group.

Step 220 may be followed by step 230 of capping the bottom of holes of the first group by curing with at least one out of UV, heat and IR.

Step 230 may be followed by step 240 of capping the top of the holes of the first group.

Step 240 may be followed by step 250 of curing the liquid ink inside the vias of the first group by a method capable of deep-curing the ink (heat, UV, etc).

At the end of method 100 and/or method 200 the holes of the second group may maintain open while at least some of the holes of the second group remain unfilled.

Method 100 and 200 can be executed after a completion of a single drilling process that forms the holes of the first and second groups. There may be no need in performing multiple different drilling processes for drilling the holes of the first group and for drilling the holes of the second group.

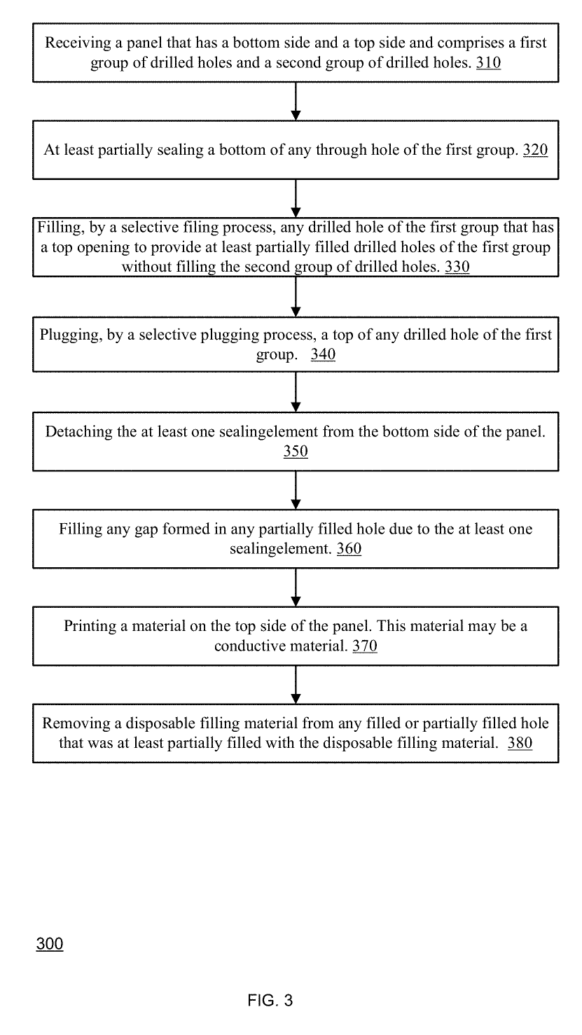

FIG. 3 illustrates method 300 according to an embodiment of the invention.

Method 300 may start by step 310 of receiving a panel that has a bottom side and a top side and comprises a first group of drilled holes and a second group of drilled holes.

Step 310 may be followed by step 320 of at least partially sealing a bottom of any through hole of the first group.

The at least partially sealing may include completely sealing or at least substantially preventing filling material to smear or otherwise substantially taint the bottom side of the panel. For example—a porous mask may allow the filling material to be drained without substantially tainting the bottom side of the panel (which is usually not flat—thereby forming gaps between the bottom openings of at last some of the drilled holes and a supporting unit).

Step 320 may include positioning at least one sealing element below the bottom side of the panel and positioning the panel on the at least one sealing element so that the at least one sealing element at least partially seals the bottom of any through hole of the first group.

The at least one sealing element may include multiple spaced apart sealing elements. The sealing elements may be positioned, shaped and sized such as to fit (or exceed) the bottom of any through hole of the first group.

The at least one sealing element can be made of a flexible material. The material may (or may not) be porous.

The flexibility of the material may allow the at least one sealing element to match the bottom side of the panel and to at least partially seal the bottom of any through hole of the first group.

The porous material allows a filling material that is deposited during step 330 to be drained without (or substantially without) tainting the bottom of the panel.

The at least one sealing elements comprise an adhesive material and it can be detachably attached to the bottom side of the panel.

Step 320 may include attaching at least one sealing element to the bottom side of the panel so that the at least one sealing element at least partially seals the bottom of any through hole of the first group.

Method 300 may include forming, before executing step 330, a conduit (such as a funnel) for conveying (during step 330) a filling material towards a drilled hole of the first group that has a top opening, during the selective filing process. This may speed up the filling process.

Step 320 may be followed by step 330 of filling, by a selective filing process, any drilled hole of the first group that has a top opening to provide at least partially filled drilled holes of the first group without filling the second group of drilled holes.

The filling process is selective in the sense that the filling material is directed towards specific locations (any drilled hole of the first group that has a top opening)—in contrary to merely immersing the entire panel within a filling material or just flooding the entire panel with the filling material.

The filling may start by forming a bottom plug.

Step 330 may be followed by step 340 of plugging, by a selective plugging process, a top of any drilled hole of the first group. Step 340 may include forming a top plug.

Step 330 of filling and step 340 of plugging may use the same filling materials or may use different filling materials.

Steps 330 and 340 may differ from each other by at least one printing parameter such as the filling materials they use, the size of filling material drops, the filling material viscosity, the printing rate, the curing parameters, and the jetting frequency.

Step 340 may be followed by step 350 of detaching the at least one sealing element from the bottom side of the panel.

Step 350 may be followed by step 360 of filling any gap formed in any partially filled hole due to the at least one sealing element.

Step 360 may be followed by step 370 of printing a material on the top side of the panel. This material may be a conductive material.

It should be noted that various steps of method 300 (including but not limited to steps 330 and 340) may be executed in parallel to (or in a non-overlapping manner) to other printing steps such as a step for printing a solder mask ink or another material on the top side of the panel.

The filling material used in step 330 and/or 340 may stay within any filled or partially filled hole or may be removed after a while. The filling material may be a disposable material that can be removed by processes such as heating. For example—the filling material may be wax or any other material that may become liquid (or even evaporate) at relatively low temperatures—that will not harm the panel.

Method 300 may include step 380 of removing a disposable filling material from any filled or partially filled hole that was at least partially filled with the disposable filling material. Step 380 may include melting the disposable filling material or vaporizing the disposable filling material.

Step 330 and/or step 340 may include curing the filling material by UV, heat or infrared (IR) radiation.

Each one of steps 330 and 340 may include one or more printing iterations. When there are multiple printing iterations each printing iteration may be followed by curing (partial or full curing). Alternatively, some or all of the printing iterations may be followed by curing.

When there are multiple printing iterations the some or all of the printing iterations (within the same step) may be identical to other printing iterations or may differ from other printing iterations by one or more printing parameters.

The formation of any top plug or bottom plug may include printing different shapes such as co-centric shapes and/or coaxial shapes such as but not limited to coaxial rings of different radiuses. For example—printing a ring around the top of the drill, followed by smaller and smaller rings. This can be used for top plugs, bottom plugs or full plugs according to the difference between ring diameters

Method 300 may include using different jetting frequencies and drop size (gray scale) to bottom plug, to fill and to top plug in order to speed up hole plugging.

When filling the holes with a disposable filling material, the disposable filling materials may be maintained within the holes to better attach the panel to a printing table—as the filled or partially filled holes prevent (or at least reduce) the dissipation of vacuum (from the printing table).

A disposable printing material (such as wax) can be left in a drilled hole and can be copper plated, so that the copper forms the a top and bottom plating on the plug. The advantage is that the plugging is reversible in case of printing defects, other defects or other reasons. The wax printing does not have a stage of UV curing and should not be heat cured.

Methods 100, 200 and 300 may be executed by a system such as an Inkjet printer that can print one or more of the following: (a) Dual ink (UV+thermal) or a single curing mechanism ink, (b) two ink types (one ink for filling+another ink for capping), (c) Interim curing at certain layers or every n layers—as the ink inside the hole may be cured by UV or IR every few passes or even in every pass.

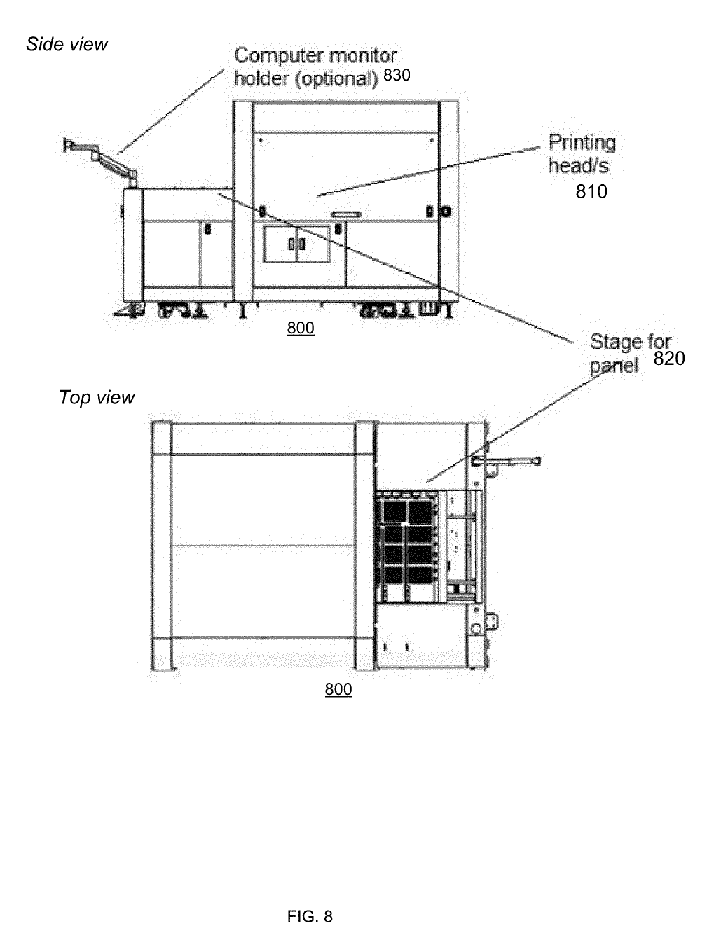

Each one of these methods may be executed by a system such as a CNC provided with an ink delivery system. See, for example, FIG. 8 that shows a system 800 that includes printing heads 810 and a stage 820 for supporting and moving the PCB and a monitor 830.

Each one of these methods may be executed by a system such as a plotter.

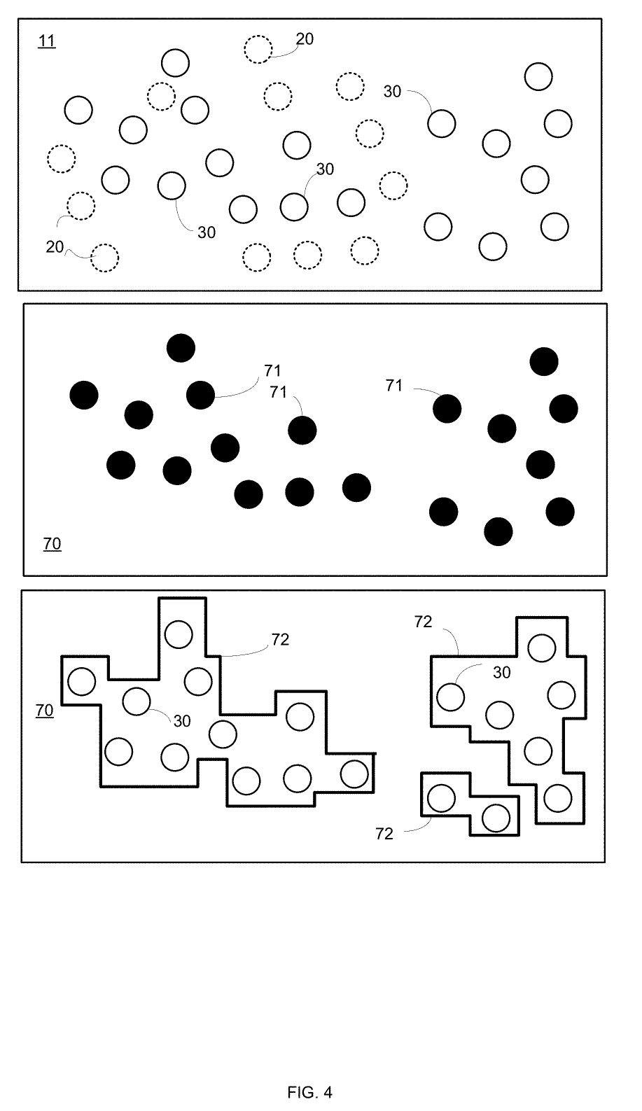

FIG. 4 illustrates a bottom side 11 of a panel. The bottom side 11 exposes bottom openings of drilled holes of the first group 30 and bottom openings of drilled holes of the second group 20.

FIG. 4 also illustrates a mask 70 that includes multiple sealing elements 71—each sealing element is positioned below each bottom opening of drilled holes of the first group 30. In FIG. 4 there are no sealing elements below the bottom opening of drilled holes of the second group 20.

FIG. 4 also shows mask that includes another pattern that includes less sealing elements (denoted 72) than bottom openings of drilled holes of the first group 30. Each sealing element may mask a region that may include one or more bottom openings of drilled holes of the first group 30.

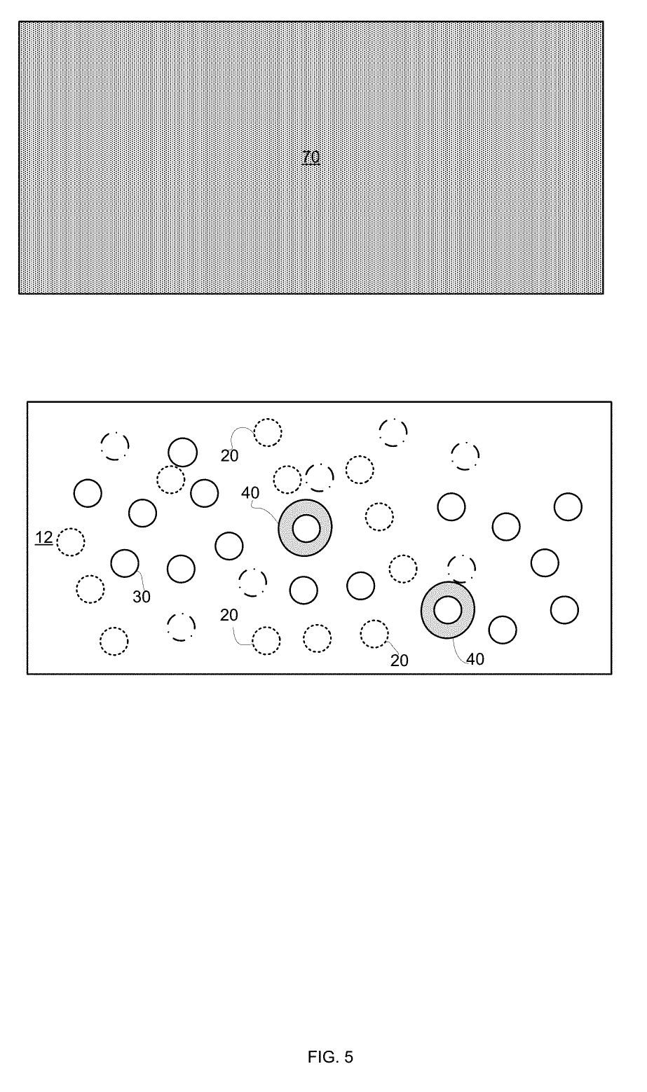

FIG. 5 illustrates a porous mask that corresponds to the entire bottom side of the panel. It is noted that when using one or more sealing elements that do not “cover” the entire bottom side of the panel—at least one sealing element can be made of a porous material.

FIG. 5 also illustrates two funnels 40 that surround two top openings of drilled holes of the first group 30. These funnels 40 are configured to direct filling material towards the holes. The funnels may have any shape and size.

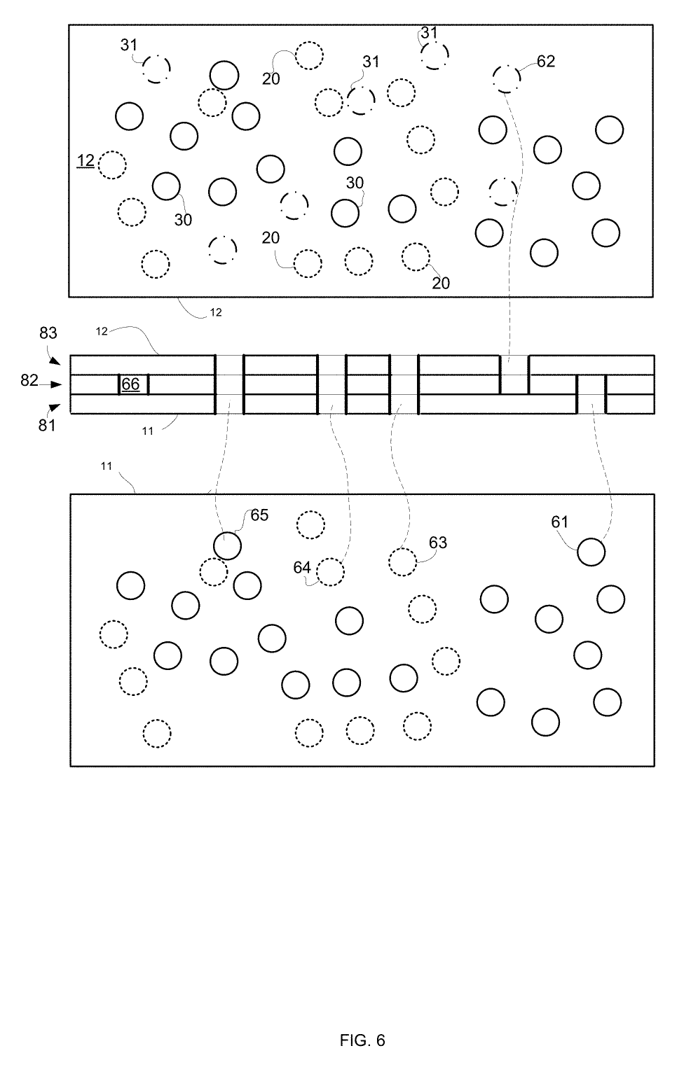

FIG. 6 illustrates the top side 12 of the panel, a bottom side of the panel and a cross sectional view of the panel. The top side 12 exposes top openings of drilled holes of the first group 30 and top openings of drilled holes of the second group 20. Top openings 31 are openings of drills of the first group 30 that do not have a bottom opening—they are not a through holes.

The cross sectional view illustrates the panel 10 as including top layer 81, intermediate layer 82 and bottom layer 82. The panel 10 includes buried via 66, a first via 61 that has a bottom opening and not a top opening, a second via 62 that includes a top opening and not a bottom opening, third through hole 61, fourth through hole 64, and fifth through hole 65.

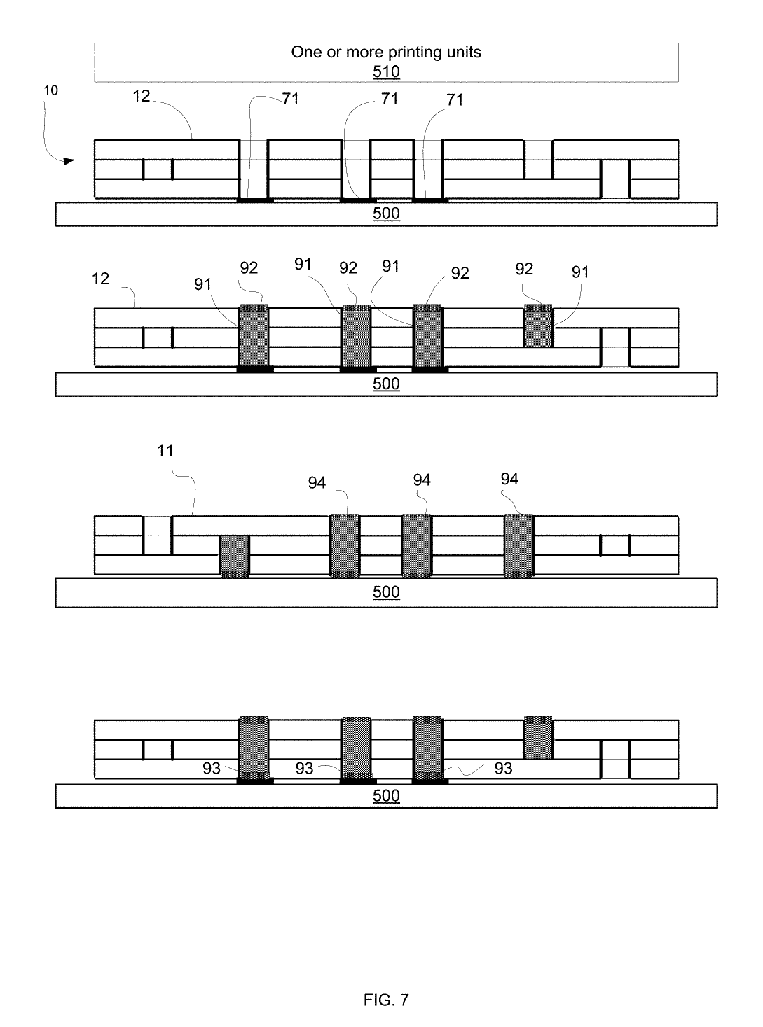

FIG. 7 illustrates a supporting unit 500 (that may be a chuck) and panel 10 at different stages of methods 100, 200 and/or 300.

The top cross section illustrates the positioning of the panel 10 on a mask that includes sealing elements 71, whereas the mask is positioned on the supporting unit 500. One or more printing units 510 are positioned above the panel 10.

The second cross section from the top of the figure illustrates the panel 10 after the filling process—in which the second till fifth drilled holes were filled with filling material 91, and after the formation of top plugs 92.

The last cross section in the figure illustrates the panel 10 as including (within third till fifth drilled holes) bottom plugs 93.

The second cross section from the bottom of the figure illustrates the panel 10 after the panel was flipped and the bottom side 11 faces upwards. In this cross section the sealing elements were removed and any gaps formed due to the usage of these sealing elements are filled—94.

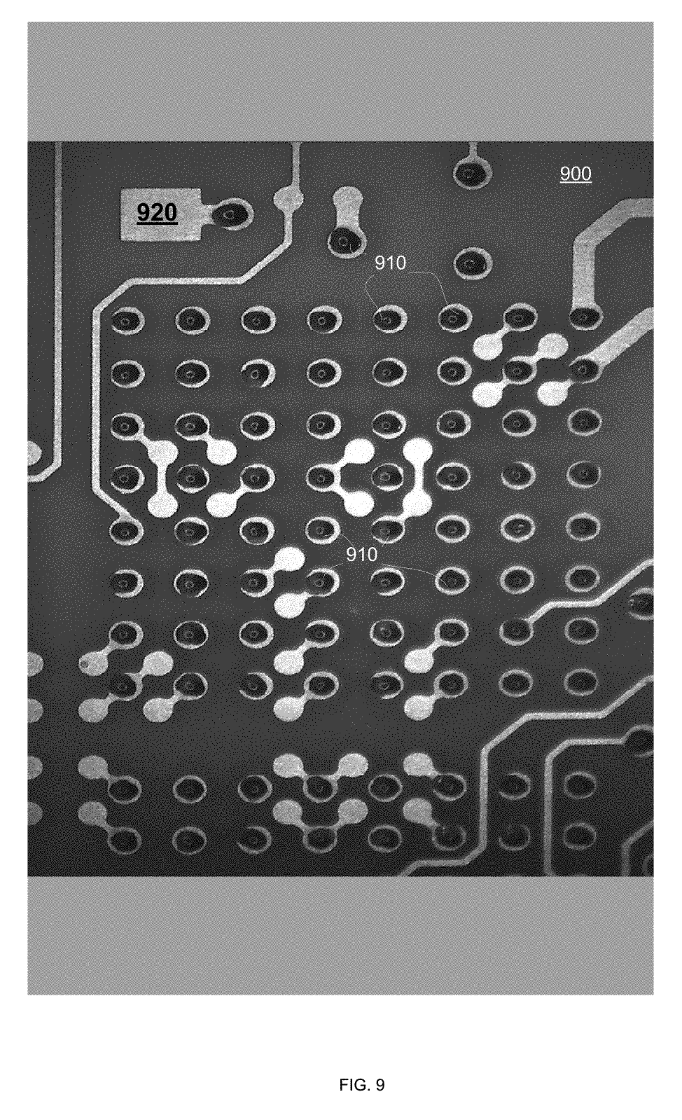

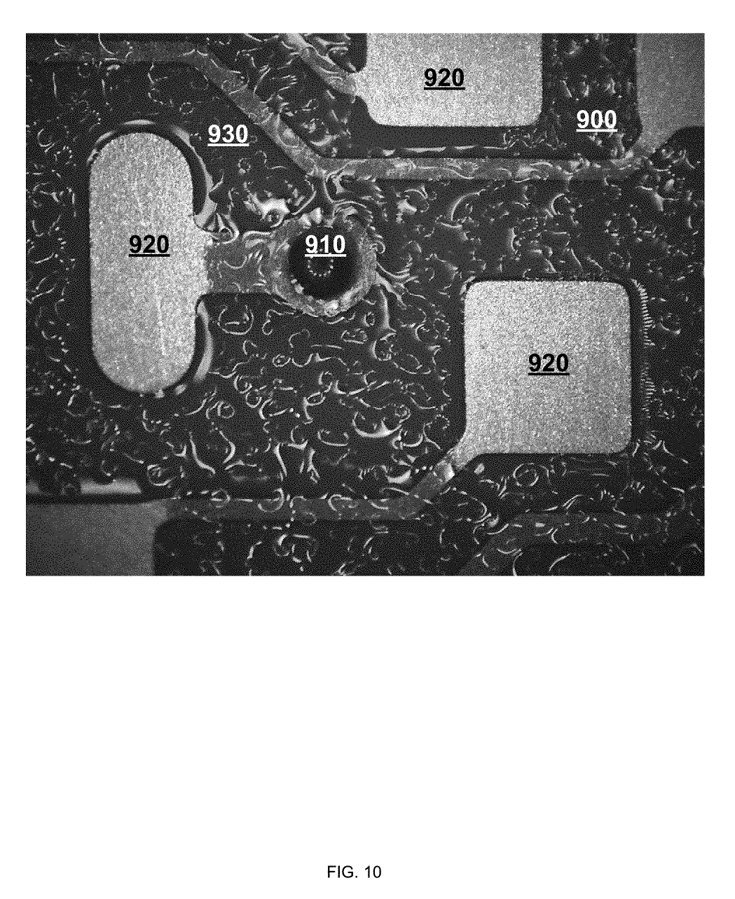

FIGS. 9 and 10 illustrate parts 900 of a PCB that include sealed vias 910 as well as pads 920 and even (see FIG. 10) a solder mask 930.

Any reference to the term “comprising” or “having” should be interpreted also as referring to “consisting of” or “essentially consisting of”. For example—a method that comprises certain steps can include additional steps, can be limited to the certain steps or may include additional steps that do not materially affect the basic and novel characteristics of the method—respectively.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps than those listed in a claim. Furthermore, the terms “a” or “an,” as used herein, are defined as one or as more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. A method for selective processing of a panel, the method comprises:
receiving a panel that has a bottom side and a top side and comprises a first group of drilled holes and a second group of drilled holes;
at least partially sealing a bottom of any through hole of the first group;
filling, by a selective filing process, any drilled hole of the first group that has a top opening to provide at least partially filled drilled holes of the first group without filling the second group of drilled holes; and
plugging, by a selective plugging process, a top of any drilled hole of the first group.

2. The method according to claim 1 wherein the at least partially sealing comprising positioning at least one sealing element below the bottom side of the panel; and positioning the panel on the at least one sealing element so that the at least one sealing element at least partially seals the bottom of any through hole of the first group.

3. The method according to claim 2 wherein the at least one sealing element comprises multiple spaced apart sealing elements.

4. The method according to claim 2 wherein the at least one sealing element is made of a flexible and porous material.

5. The method according to claim 2 wherein the at least one sealing element comprise an adhesive material.

6. The method according to claim 2 wherein the at least one sealing element comprises a pressure sensitive adhesive film.

7. The method according to claim 1 wherein the at least partially sealing comprising attaching at least one sealing element to the bottom side of the panel so that the at least one sealing element at least partially seals the bottom of any through hole of the first group.

8. The method according to claim 7 further comprising detaching the at least one sealing element from the bottom side of the panel.

9. The method according to claim 8 further comprising filling any gap formed in any partially filled hole due to the at least one sealing element.

10. The method according to claim 1 wherein the selective filing process differs from the selective plugging process by at least one printing parameter.

11. The method according to claim 10 wherein the at least one printing parameter comprising filling materials used for printing, a size of filling material drops, a filling material viscosity, a printing rate, a curing parameter, and a jetting frequency.

12. The method according to claim 1 further comprising forming a conduit for conveying a filling material towards a drilled hole of the first group that has a top opening, during the selective filing process.

13. The method according to claim 1 further comprising forming a funnel for conveying a filling material towards a drilled hole of the first group that has a top opening, during the selective filling process.

14. The method according to claim 1 wherein the at least partially sealing comprises sealing the bottom of any through hole of the first group.

15. The method according to claim 1 wherein the plugging of the selective plugging process comprises curing filling material used for sealing any drilled hole of the first group that has a top opening.

16. The method according to claim 1 further comprising printing a material on the top side of the panel after plugging, by the selective plugging process, the top of any drilled hole of the first group.

17. The method according to claim 1 further comprising printing a material on the top side of the panel while plugging, by the selective plugging process, the top of any drilled hole of the first group.

18. The method according to claim 1 wherein the selective filling process comprising filling of any drilled hole of the first group that has the top opening with a disposable material; and removing the disposable material at a point in time that follows the plugging, by the selective plugging process, the top of any drilled hole of the first group.

19. The method according to claim 18 comprising removing the disposable material by melting the disposable material.

20. The method according to claim 18 comprising removing the disposable material by heating the disposable material.

21. The method according to claim 18 wherein the disposable material is wax.
